(19) United States
(12) Patent Application Publication
(10) Pub. No.: US 2014/0349120 A1
(43) Pub. Date: Nov. 27, 2014

(54) Epoxy Resin Composition and High Frequency Circuit Board Manufactured by Using the Same

(71) Applicant: Xianping Zeng, Dongguan city (CN)

(72) Inventor: Xianping Zeng, Dongguan city (CN)

(73) Assignee: Shengyi Technology Co., Ltd., Guangdong (CN)

(21) Appl. No.: 14/352,389

(22) PCT Filed: Oct. 18, 2011
(86) PCT No.: PCT/CN2011/080925

§ 371 Date: Aug. 11, 2014

(51) Int. Cl. H05K 1/03; C08L 63/04

(52) U.S. Cl. CPC H05K 1/0353; C08L 63/04; H05K 1/0373; C08L 2201/02; C08L 2203/20; H05K 2201/012
USPC 428/416; 525/472; 523/400; 523/456; 523/462; 523/451; 523/445

(57) ABSTRACT

Disclosed are an epoxy resin composition and a high frequency circuit board manufactured by using the same, and the epoxy resin composition comprises the following solid components: (A) a cyanate compound having at least two cyanoxy groups or its prepolymer, (B) an active ester, and (C) an epoxy resin containing a naphthol structure. The total amount of the component (A) a cyanate compound having at least two cyanoxy groups or its prepolymer and the component (B) an active ester is 10-70 parts by weight, and the amount of component (C) an epoxy resin containing a naphthol structure is 30-90 parts by weight, based on the parts by weight of these solid components, wherein the weight ratio of the component (A) a cyanate compound having at least two cyanoxy groups or its prepolymer to the component (B) an active ester is 0.2-5 to 1. The high frequency circuit board manufactured by using the epoxy resin composition comprises multiple layers of laminated semi-cured sheets and copper foils press-bonded on both sides of them, and each of the multiple layers of laminated semi-cured sheets comprises a substrate and the epoxy resin composition attached on it by impregnating and drying.

### TECHNICAL FIELD

The present invention relates to a resin composition, and in particular relates to an epoxy resin composition and a high frequency circuit board manufactured by using the same.

### BACKGROUND ART

With the high speed and multifunction of the electronic information processing, and the continuously improvement of the application frequency, 3-6 GHz will become mainstream. In addition to maintaining a higher demand on the heat resistance of the laminate materials, the dielectric constant and dielectric loss value will demand lower and lower. Existing traditional FR-4 material is difficult to meet the needs of high-frequency and high-speed development of electronic products, while the substrate material is no longer a mechanical support role played in the traditional sense, rather, it will, together with electronic components, become an important way for PCB and terminal manufacturers designers to improve the product performance. High DK causes the signal transfer rate slow, and high Df causes the signal partly convert into heat loss in the substrate material, so reducing the DK/Df has become the hot pursuit of the substrate industry. Conventional FR-4 material mainly uses dicyandiamide as a curing agent. This curing agent has good process operability for a tertiary amine reaction, but due to high cracking at high temperatures for the weak carbon-nitrogen bond, which results the condensate has lower decomposition temperature and is unable to adapt to the heat requirements of lead-free processes. In this context, cyanate ester resin having excellent dielectric properties has become one of the hot high-profile. Nonetheless, cyanate ester resin has its own limitations, including poor wet-heat resistance and easiness of delamination at high temperature.

Japanese Patent Publication No. Sho 46-41112, Laid-Open Patent Publication No. Sho 50-132099 and Laid-Open Patent Publication No. Sho 57-143320 propose a scheme, in which common used epoxy resins such as bisphenol A epoxy resin, brominated bisphenol A epoxy resin, phenol novolac epoxy resin and phenol novolac cresol epoxy resin are mixed with cyanate ester resin to form a resin composition. The resin composition further improves wet-heat resistance compared with cyanate ester unitary system, but greatly determines dielectric properties of cyanate ester resin due to influence of epoxy resin. Thus, in Japanese Patent Laid-Open Publication No. 8-176273, JP Patent Publication No. 8-176274 and Patent Publication No. 11-60692 propose to select specific epoxy resin such as naphthalene ring-containing epoxy resin, biphenyl structure-containing epoxy resin, lower alkyl-substituted phenol salicylaldehyde novolac epoxy resin, and dicyclopentadiene-containing epoxy resin to mix with cyanate ester resin. This mixture improves dielectric properties compared with common used epoxy resin composition, but greatly reduces glass transition temperature due to reduction of crosslinking density of the epoxy resin.

### SUMMARY

One object of the present invention is to provide an epoxy resin composition, which can provide excellent dielectric properties, wet-heat resistance and high glass transition temperature required by high-frequency circuit substrate.

Another object of the present invention is to provide a high-frequency circuit board having excellent dielectric properties and wet-heat resistance and having high glass transition temperature at the same time which is manufactured by using the above-mentioned epoxy resin composition.

To achieve the above objects, the present invention provides an epoxy resin composition, comprising the following solid components:
(A) cyanate ester compound having at least two cyanato groups or its prepolymer,
(B) active ester, and
(C) epoxy resin containing naphthol structure;
   based on the parts by weight of the solid components, the total usage of the component (A) cyanate ester compound having at least two cyanato groups or its prepolymer and the component (B) active ester is 30-90 parts by weight, wherein the weight ratio between the component (A) cyanate compound having at least two cyanoxy groups or its prepolymer and the component (B) active ester is 0.2-5:1.

The component (A) cyanate compound having at least two cyanato groups or its prepolymer includes at least one cyanate ester compound having the following structural formula or its prepolymer:

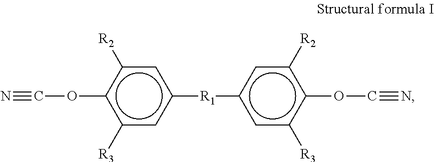

wherein R1 represents

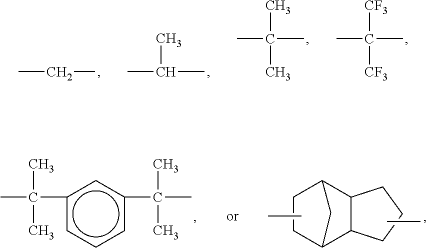

R2 and R3 may be same or different, each represents hydrogen atom or alkyl group having 1 to 4 carbon atoms;

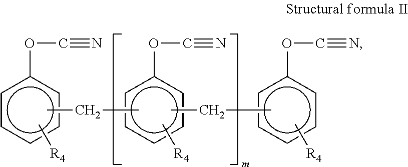

wherein R4 represents hydrogen atom or alkyl group having 1-4 carbon atoms and m is an integer of 1-7.

The component (A) cyanate ester compound containing at least two cyanato groups in the molecule or its prepolymer is one or more selected from the group consisting of 2,2-bis(4-cyano-phenyl)propane, bis(4-cyano-phenyl)ethane, bis(3,5-dimethy-4-cyanatophenyl)methane, 2,2-bis(4-cyano-phenyl)-1,1,1,3,3,3-hexafluoropropane, α,α′-bis(4-cyano-phenyl)-1,3-bis(isopropyl)benzene, cyclopentadiene cyanate, phenol novolac cyanate and cresol novolac cyanate, or prepolymer thereof. Preferably, the component (A) cyanate ester compound containing at least two cyanato groups in the molecule or its prepolymer is one or more selected from the group consisting of 2,2-bis(4-cyano-phenyl)propane, bis(3,5-dimethy-4-cyanatophenyl)methane and α,α′-bis(4-cyano-phenyl)-1,3-bis(isopropyl)benzene, or prepolymer thereof.

The component (B) active ester includes active ester of the following structural formula:

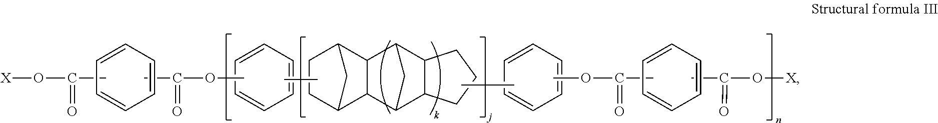

wherein:
X is benzene ring or naphthalene ring,
j is 0 or 1,
k is 0 or 1,
n means the average repeating unit and is 0.25-1.25.

The component (C) epoxy resin containing naphthol structure has the following structural formula:

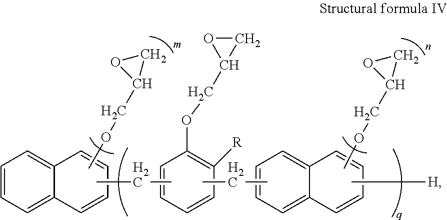

wherein m and n are 1 or 2 respectively,
q is an integer between 1 and 10,
R is H or alkyl group having 1-5 carbon atoms.

The epoxy resin composition further comprises a flame retardant, wherein the flame retardant is mixed preferably in 5-100 parts by weight based on 100 part by weight of the sum of component (A), component (B) and component (C); the flame retardant is a bromine-containing flame retardant or a non-halogen flame retardant, wherein the bromine-containing flame retardant is selected from decabromodiphenyl ether, decabromodiphenyl ethane, brominated styrene or ethylenebistetrabromophthalimide, and the non-halogen flame retardants is selected from tri(2,6-dimethyphenyl)phosphine, 10-(2,5-dihydroxyphenyl)-9,10-dihydrogen-9-oxa-10-phosphenanthrene-10-oxide, 2,6-bis(2,6-dimethylphenyl)phosphenyl, 10-phenyl-9,10-dihydrogen-9-oxa-10-phosphenanthrene-10-oxide, phenoxy phosphonic cyanide compounds or zinc borate.

The epoxy resin composition further comprises an inorganic filler, the filler is mixed preferably in 5-500 parts by weight based on 100 parts by weight of the sum of component (A), component (B) and component (C), wherein the inorganic filler is one or more selected from the group consisting of crystalline silica, fused silica, spherical silica, aluminum nitride, boron nitride, titanium oxide, strontium titanate, barium titanate, alumina, barium sulfate, talc powder, calcium silicate, calcium carbonate, mica, and polytetrafluoroethylene; and wherein the particle size of the inorganic filler is 0.01-50 μm.

At the same time, the present invention also provides a high-frequency circuit board manufactured by using the above-mentioned epoxy resin composition, comprising several stacked prepregs and copper foils cladded on both sides of the stacked prepregs, wherein the prepregs all include the epoxy resin composition adhering thereon by impregnating and then drying.

The high frequency electronic-circuit board is prepared by cladding the copper coil on both sides of the stacked prepregs and curing in a hot press machine, wherein the curing temperature is 150-250° C. and the curing pressure is 25-60 Kg/cm².

The present invention has the following beneficial effects:
\textcircled{1} the epoxy resin composition of the present invention use cyanate ester and active ester as compound curing agents, achieving the advantages of high glass transition temperature and good dielectric properties of cyanate ester,and overcoming the defect of poor wet-heat resistance;
\textcircled{2} the epoxy resin composition of the present invention use cyanate ester and active ester as curing agents, fully achieving the advantages of excellent dielectric properties and good wet-heat resistance due to the fact that no polar hydroxyl group is generated in the reaction between active ester and epoxy resin; and use a epoxy resin containing specific naphthol structure, further reducing water absorption of cured resin, and addressed the disadvantage of relatively low glass transition temperature;
\textcircled{3} the epoxy resin composition of the present invention also comprises epoxy resin having at least one naphthol structure, wherein the naphthol group in the epoxy resin presents hydrophobic property and high rigidity, and thus the circuit board manufactured by using epoxy resin composition and the above-mention compound curing agents can further optimize dielectric properties and have high glass transition temperature after curing;
\textcircled{4} the high-frequency circuit board manufactured by using the above-mentioned epoxy resin composition of the present invention has excellent dielectric properties and wet-heat resistance, and has high glass transition temperature at the same time.

### DETAILED DESCRIPTION

The epoxy resin composition of the present invention includes the following solid components:
(A) cyanate ester compound having at east two cyanato groups or its prepolymer,
(B) active ester, and
(C) epoxy resin containing naphthol structure;
   based on the parts by weight of the solid components, the total usage amount of the component (A) cyanate ester compound having at least two cyanato groups or its prepolymer and the component (B) active ester is 30-90 parts by weight, wherein the weight ratio between the component (A) cyanate compound having east two cyanoxy groups or its prepolymer and the component (B) active ester is 0.2-5:1.

There is no limitation on the component (A) cyanate ester compound having at least two cyanato groups in the molecule. As long as the molecule has at least two cyano groups in the molecule, it can conduct crosslinking to be cured. The cyanate compound having at least two cyanato groups in the molecule can include at least one cyanate ester compound having the following structural formula or its prepolymer:

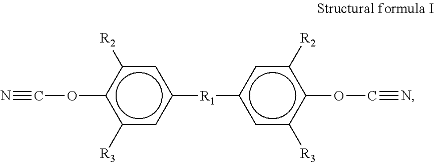

wherein R1 represents

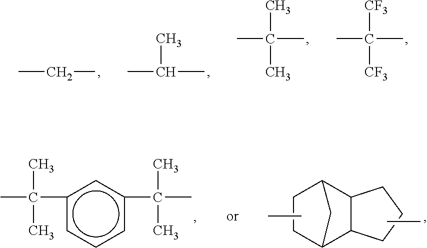

R2 and R3 may be same or different, each represents hydrogen atom or alkyl group having 1 to 4 carbon atoms;

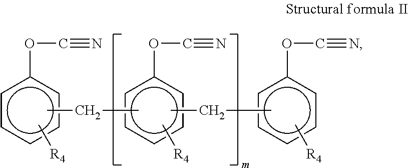

wherein R4 represents hydrogen atom or alkyl group having 1-4 carbon atoms and m represents an integer between 1 and 7.

The cyanate ester compound having at least two cyanato groups in the molecule of component (A), forms cyanate ester oligomer having thiotriazinone. There is special limitation on the conversion of cyanato in the oligomer. The oligomer can be prepolymer of the cyanate ester compound having structural formula I or II. The component (A) cyanate ester compound containing at least two cyanato groups in the molecule or its prepolymer is one or more selected from the group consisting of 2,2-bis(4-cyano-phenyl)propane, bis (4-cyano-phenyl)ethane, bis(3,5-dimethy-4-cyanatophenyl)methane, 2,2-bis(4-cyano-phenyl)-1,1,1,3,3,3-hexafluoropropane, α,α′-bis(4-cyano-phenyl)-1,3-bis(isopropyl)benzene, cyclopentadiene cyanate, phenol novolac cyanate and cresol novolac cyanate, or prepolymer thereof. Preferably, the component (A) cyanate ester compound containing at least two cyanato groups in the molecule or its prepolymer is one or more selected from the group consisting of 2,2-bis(4-cyano-phenyl)propane, bis(3,5-dimethy-4-cyanatophenyl)methane and α,α′-bis(4-cyano-phenyl)-1,3-bis(isopropyl)benzene, or prepolymer thereof. These compounds can be used alone or in combination.

The component (B) of the present invention is an active ester containing specific structure. The ester group conducts a curing reaction with epoxy resin without generating polar group —OH, thus wet resistance and dielectric properties are good. The structural formula can be represented as follows:

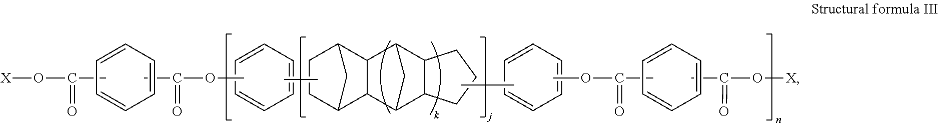

wherein:
X is benzene ring or naphthalene ring,
j is 0 or 1,
k is 0 or 1,
n means the average repeating unit and is 0.25-1.25.

The specific rigid structures in the active ester such as benzene ring, naphthalene ring, cyclopentadiene render it high wet resistance; the structural orderliness of the active ester render it good dielectric properties.

The epoxy resin composition of the present invention introduces the above-mentioned active ester, which forms compound curing agent together with the cyanate ester. Cyanate ester-modified epoxy resin has poor wet resistance mainly because of wet-heat decomposition of the thiotriazinone structure formed in curing and residual cyanate ester groups. Therefore, to resolve the wet-heat resistance problem, the two kinds of groups should be reduced. Nonetheless, thiotriazinone structure has unique advantages such as high glass transition temperature and good dielectric properties. Therefore, the cyanate ester and active the ester form compound curing agents together can reduce the ration of thiotriazinone to address the problem of poor wet-heat resistance, and improve both dielectric properties and wet-heat resistance, and overcomes the disadvantage of relatively low glass transition temperature. The weight ratio of the component (A) a cyanate compound having at least two cyanoxy groups in the molecule or its prepolymer to the component (B) an active ester is 0.2-5 to 1, preferably 0.2-3:1, more preferably 0.3-3:1.

The component (C) epoxy resin containing naphthol has the following formula IV:

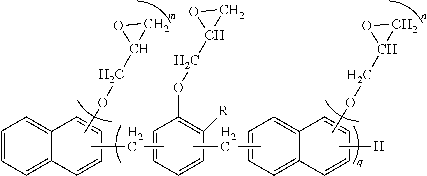

wherein m and n are 1 or 2 respectively,
q is an integer between 1 and 10,
R is H or alkyl group having 1-5 carbon atoms.

The above-mentioned component (C) epoxy resin containing naphthol structure can be the more specific following structural formulas:

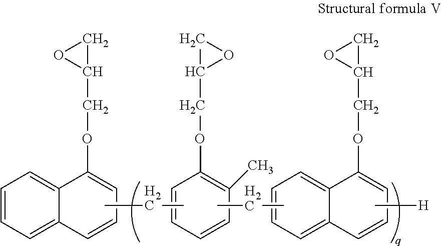

wherein q is an integer between 1 and 10;

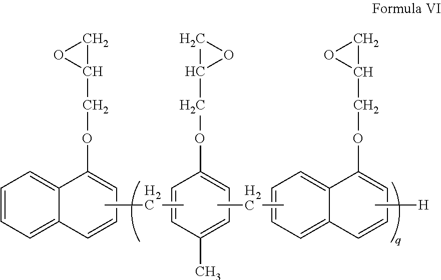

wherein q is an integer between 1 and 10; or

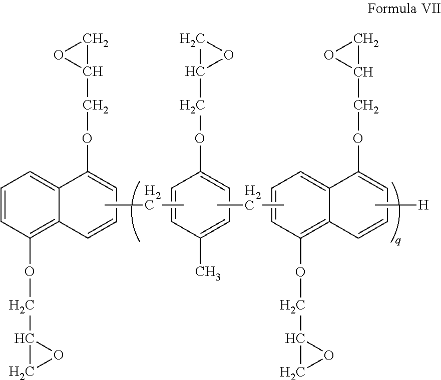

In the present invention, component (C) is used in an amount of 30-90 parts by weight, preferably 40-90 parts by eight.

The above-mentioned epoxy resin composition can further comprise flame retardants, inorganic fillers and other additives as long as dielectric properties and heat resistance are not affected.

There is no specific limitation on the flame retardant added as needed. It is better to use non-reactive flame retardant and it is better without affecting dielectric properties. The flame retardant can be a bromine-containing flame retardant or a non-halogen flame retardant, wherein the bromine-containing flame retardant is selected from the group consisting of decabromodiphenyl ether, decabromodiphenyl ethane, brominated styrene or ethylenebistetrabromophthalimide, and the non-halogen flame retardants is selected from tri(2,6-dimethyphenyl)phosphine, 10-(2,5-dihydroxyphenyl)-9,10-dihydrogen-9-oxa-10-phosphenanthrene-10-oxide, 2,6-bis(2,6-dimethylphenyl)phosphenyl, 10-phenyl-9,10-dihydrogen-9-oxa-10-phosphenanthrene-10-oxide, phenoxy phosphonic cyanide compounds or zinc borate. The flame retardant is mixed in 5 to 100 parts by weight based on 100 parts by weight of the sum of component (A), component (B) and component (C); more preferably 5 to 90 parts by weight; particularly preferably 5 to 80 parts by weight.

There is no specific limitation on the filler added as needed. The inorganic filler can be one or more selected from the group consisting of crystalline silica, fused silica, spherical silica, aluminum nitride, boron nitride, titanium oxide, strontium titanate, barium titanate, alumina, barium sulfate, talc powder, calcium silicate, calcium carbonate, mica, and polytetrafluoroethylene. In addition, there is no specific limitation on shape and particle size of the inorganic filler. The particle size of the inorganic filler is usually 0.01-50 um, preferably 0.01 to 20 um, particularly preferably 0.1 to 10 um. It is easier to disperse for this range of the particle size. Furthermore, there is no specific limitation on the dosage of the filler. Preferably, the filler is used in 5-1000 parts by weight based on 100 parts by weight of the sum of component (A), component (B) and component (C), more preferably 5-800 parts by weight, particularly preferably 5-200 parts by weight.

The specific method for preparing high frequency circuit board by using the above-mentioned epoxy resin composition is as follows: to a container adding solid components and then liquid solvent, stirring till completely resolved, adding liquid resin, filler, flame retardant and accelerant, continually stirring evenly to obtain glue; impregnating glass fabric into the glue, control to a suitable thickness and dying to remove the solvent, thereby obtaining prepreg; cladding the copper coil on both sides of the stacked prepregs and curing in a hot press machine, wherein the curing temperature is 150-250° C. and the curing pressure is 25-60 Kg/cm².

The high frequency circuit board manufactured comprises: several stacked prepregs and copper foils respectively cladded on both sides of the stacked prepregs, wherein the prepregs all include substrate and epoxy resin composition adhering thereon by impregnating and then drying. The substrate can use natural fiber, organic synthesis fiber, organic fabric and inorganic fiber, for example, glass fabric.

For high frequency circuit board made as mentioned above, dielectric constant, dielectric loss factor, glass transition temperature and wet-heat resistance are all measured, and further described referring to the following embodiments.

### Embodiment 1

To a container were added naphthol novolac epoxy resin NC-7300L in 60 parts by weight, bisphenol A cyanate ester resin HF-10 in 18 parts by weight and HPC-8000-65T in 22 parts by weight. The mixture was stirred, then to it were added appropriate amount of accelerant zinc dioctanoate and DMAP in addition to the solvent toluene, obtaining a glue after stirring to uniformity. Glass fabric is impregnated into the glue solution, and are controlled to an appropriate thickness. Then the glass fiber cloth is dried to remove the solvent, thereby obtaining a prepreg. Several such prepregs are stacked, and two copper foils are cladded on both sides of the stacked prepregs, obtaining a high frequency circuit board in a hot press machine. Physical property data of the copper-clad laminate is shown in Table 1.

### Embodiments 2 to 4

The manufacturing process is the same as that in embodiment 1. The formulas and physical property data are shown in Table 1.

### COMPARISON EXAMPLE 1 TO 3

The manufacturing process is the same as that in embodiment 1. The formulas and physical property data are shown in Table 1.

TABLE 1
Formulas and Physical Property Data of Embodiments and Comparative Examples

| | | | | | Comparative | Comparative | Comparative |
|---|---|---|---|---|---|---|---|
| Component | Embodiment 1 | Embodiment 2 | Embodiment 3 | Embodiment 4 | Example 1 | Example 2 | Example 3 |
| NC-7300L | 60 | — | — | 60 | 60 | 50 | — |
| NC-7000L | — | 60 | — | — | — | — | — |
| NC-7700L | — | — | 65 | — | — | — | — |
| HP-7200H | — | — | — | — | | — | — |
| N-690 | — | — | — | — | — | — | 60 |
| HF-10 | 22 | 20 | 22 | 20 | 1eq | | 1eq |
| PT-30 | — | — | — | 20 | — | — | — |
| HPC-8000-65T | 22 | 20 | 22 | 20 | 1eq | — | 1eq |
| zinc | 0.015 | 0.015 | 0.015 | 0.015 | — | 0.1 | — |
| dioctanoate | | | | | | | |
| DMAP | 0.06 | 0.06 | 0.06 | 0.06 | 0.15 | — | 0.2 |
| Tg (DMA)/° C. | 210 | 215 | 220 | 230 | 170 | 230 | 160 |
| Dk (10 g) | 3.7 | 3.8 | 3.8 | 3.8 | 3.8 | 3.8 | 3.85 |
| Df (10 g) | 0.006 | 0.007 | 0.007 | 0.0075 | 0.0085 | 0.0009 | 0.0015 |
| PCT/2 h | 3/3 | 3/3 | 3/3 | 3/3 | 3/3 | 1/3 | 2/3 |

The materials listed in the table are particularly as follows:
NC-7300L: naphthol novolac epoxy resin with epoxy equivalent of 214 g/eq;
NC-7000L: naphthol novolac epoxy resin with epoxy equivalent of 232 g/eq;
NC-7700L: naphthol novolac epoxy resin with epoxy equivalent of 233 g/eq;
HP-7200-H: dicyclopentadiene novolac epoxy resin with epoxy equivalent: of 280 g/eq;
N-690: o-cresol novolac epoxy resin with epoxy equivalent of 215 g/eq;
HF-10: bisphenol A cyanate ester resin polymer;
PT-30: phenol formaldehyde cyanate;
HPC-8000-65T: active ester curing agent with active ester equivalent of 223 g/eq;
TD-2090: linear novolac curing agent with hydroxyl group equivalent of 105 g/eq;
DMAP: 4-dimethylaminopyridine.

The test method of the above properties is as follows:
(1) glass transition temperature (Tg): measured via the DMA assay prescribed in accordance with IPC-TM-650 2.4.24.
(2) dielectric constant and dielectric loss factor: measured according to SPDR method.
(3) wet-heat resistance evaluation after PCT: the substrate lamina was evaluated after the copper foil on the surface of copper-clad laminate was etched; the substrate lamina is placed in a pressure cooker, and treated at 120° C. and under 105 KPa for 2h; then the substrate lamina is impregnated in a tin furnace at 288° C.; once the substrate lamina is delaminated, record the corresponding time; if no bubble or delamination occurred after the substrate lamina was in a tin furnace for 5 min, the evaluation can be finished.

### Physical Properties Analysis

As can be known from the physical property data shown in Table 1: for comparative examples 1 using the naphthol epoxy resin and being cured only by active ester, the dielectric properties are improved compared with common used epoxy resin, and the wet-heat resistance is good, but the glass transition temperature is low; for comparative example 2 having same structure and being cured by a cyanate resin, the glass transition temperature is high, and the dielectric properties is improved, but the wet-heat resistance is poor; for comparative example 3 using active ester as curing agent, the wet-heat resistance is good, but the dielectric properties are poor; for embodiments 1-4 co-cured using epoxy resin containing naphthol structure and active ester, the obtained cured product has better dielectric properties compared with common used novolac resin, and has high glass transition temperature and good wet-heat resistance.

In summary, compared with the common used copper-clad board, the high frequency circuit board of the present invention has more excellent dielectric properties, and has high glass transition temperature and good wet-heat resistance at the same time.

The above embodiments are merely preferred examples of the present invention. Those skilled in the art can make numerous variations and changes according to the technical solution and spirit of the present invention, all of which fall into the protected scope prescribed by the claims of the present invention.

1. An epoxy resin composition, comprising the following solid components:
(A) cyanate ester compound having at least two cyanato groups in the molecule or its prepolymer,
(B) active ester, which comprises an active ester of the following structural formula: 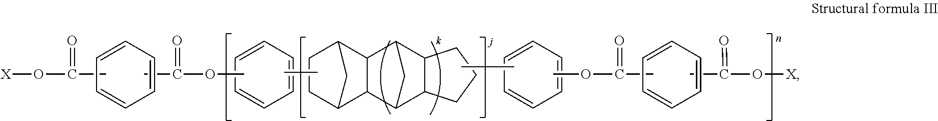
wherein:
X is benzene ring or naphthalene ring,
j is 0 or 1,
k is 0 or 1,
n means the average repeating unit and is 0.25-1.25; and
(C) epoxy resin containing naphthol structure;
based on the parts by weight of the solid components, the total usage amount of the component (A) cyanate compound having at least two cyanato groups or its prepolymer and the component (B) active ester is 30-90 parts by weight, wherein the weight ratio between the component (A) cyanate ester compound having at least two cyanato groups or its prepolymer and the component (B) active ester is 0.2-5:1.

2. The epoxy resin composition according to claim 1, wherein the component (A) cyanate ester compound having at least two cyanato groups in the molecule or its prepolymer includes at least one cyanate ester compound having the following structural formula or its prepolymer: 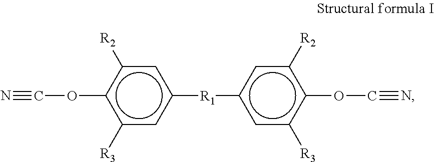
wherein R1 represents 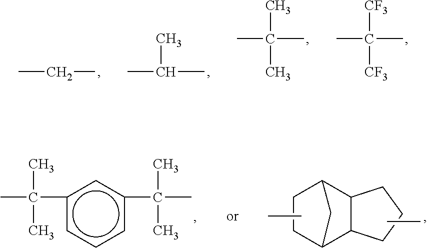
R2 and R3 may be same or different, each represents hydrogen atom or alkyl group having 1 to 4 carbon atoms; 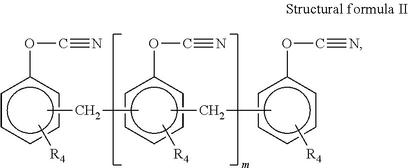
wherein R4 represents hydrogen atom or alkyl group having 1-4 carbon atoms and m is an integer of 1-7.

3. The epoxy resin composition according to claim 1, wherein the component (A) cyanate ester compound containing at least two cyanato groups in the molecule or its prepolymer is one or more selected from the group consisting of 2,2-bis(4-cyano-phenyl)propane, bis(4-cyano-phenyl)ethane, bis(3,5-dimethy-4-cyanatophenyl)methane, 2,2-bis(4-cyano-phenyl)-1,1,1,3,3,3-hexafluoropropane, α,α′-bis(4-cyano-phenyl)-1,3-bis(isopropyl)benzene, cyclopentadiene cyanate ester, phenol novolac cyanate ester and cresol novolac cyanate ester, or prepolymer thereof.

4. The epoxy resin composition according to claim 3, wherein the component (A) cyanate compound containing at least two cyanato groups in the molecule or its prepolymer is one or more selected from the group consisting of 2,2-bis(4-cyano-phenyl)propane, bis(3,5-dimethy-4-cyanatophenyl)methane and α,α′-bis(4-cyano-phenyl)-1,3-bis(isopropyl)benzene, or prepolymer thereof.

5. The epoxy resin composition according to claim 1, wherein the component (C) epoxy resin containing naphthol structure has the following structural formula: 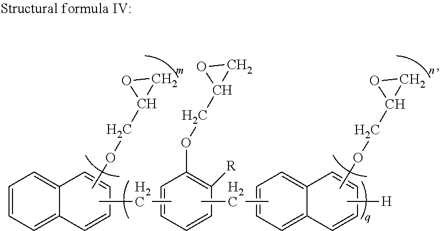
wherein m and n are 1 or 2 respectively,
q is an integer between 1 and 10,
R is H or alkyl group having 1-5 carbon atoms.

6. The epoxy resin composition according to claim 1, further comprising a flame retardant, wherein the flame retardant is mixed in 5-100 parts by weight based on 100 part by weight of the sum of component (A), component (B) and component (C); the flame retardant is a bromine-containing flame retardant or a non-halogen flame retardant, wherein the bromine-containing flame retardant is selected from the group consisting of decabromodiphenyl ether, decabromodiphenyl ethane, brominated styrene or ethylenebistetrabromophthalimide, and the non-halogen flame retardants is selected from tri(2,6-dimethyphenyl)phosphine, 10-(2,5-dihydroxyphenyl)-9,10-dihydrogen-9-oxa-10-phosphenanthrene-10-oxide, 2,6-bis(2,6-dimethylphenyl)phosphenyl, 10-phenyl-9,10-dihydrogen-9-oxa-10-phosphenanthrene-10-oxide, phenoxy phosphonic cyanide compounds or zinc borate.

7. The epoxy resin composition according to claim 1, further comprising an organic or inorganic filler, wherein the inorganic filler is mixed preferably in 5-500 parts by weight based on 100 parts by weight of the sum of component (A), component (B) and component (C); the inorganic filler is one or more selected from the group consisting of v; and wherein the particle size of the inorganic filler is 0.01-50 μm.

8. A high frequency circuit board manufactured by using the epoxy resin composition according to claim 1, comprising several stacked prepregs and copper foils cladded on both sides of the stacked prepregs, wherein the prepregs all include the epoxy resin composition adhering thereon by impregnating and then drying.

9. A high frequency circuit board manufactured according to claim 8, wherein the high frequency circuit board is prepared by cladding the copper coil on both sides of the stacked prepregs and curing in a hot press machine, wherein the curing temperature is 150-250° C. and the curing pressure is 25-60 Kg/cm².
